(19) United States
(12) Patent Application Publication
(10) Pub. No.: US 2017/0162235 A1
(43) Pub. Date: Jun. 8, 2017

(54) SYSTEM AND METHOD FOR MEMORY MANAGEMENT USING DYNAMIC PARTIAL CHANNEL INTERLEAVING

(71) Applicant: QUALCOMM INCORPORATED, SAN DIEGO, CA (US)

(72) Inventors: SUBRATO DE, SAN DIEGO, CA (US); RICHARD STEWART, SAN DIEGO, CA (US); DEXTER TAMIO CHUN, SAN DIEGO, CA (US)

(21) Appl. No.: 14/957,045

(22) Filed: Dec. 2, 2015

(51) Int. Cl. G11C 7/10; G06F 12/06; G06F 3/06; G06F 13/16

(52) U.S. Cl. CPC G11C 7/1072; G06F 13/1657; G06F 12/0607; G06F 3/0653; G06F 3/0685; G06F 3/061

(57) ABSTRACT

Systems and methods are disclosed for providing memory channel interleaving with selective power/performance optimization. One such method comprises configuring an interleaved zone for relatively higher performance tasks, a linear address zone for relatively lower power tasks, and a mixed interleaved-linear zone for tasks with intermediate performance requirements. A boundary is defined among the different zones using a sliding threshold address. The zones may be dynamically adjusted, and/or new zones dynamically created, by changing the sliding address in real-time based on system goals and application performance preferences. A request for high performance memory is allocated to a zone with lower power that minimally supports the required performance, or may be allocated to a low power memory zone with lower than required performance if the system parameters indicate a need for aggressive power conservation. Pages may be migrated between zones in order to free a memory device for powering down.

### DESCRIPTION OF THE RELATED ART

Many computing devices, including portable computing devices such as mobile phones, include a System on Chip (“SoC”). Today's SoCs require ever increasing levels of power performance and capacity from memory devices, such as double data rate (“DDR”) memory devices. Such requirements necessitate relatively faster clock speeds and wider busses, the busses typically being partitioned into multiple, narrower memory channels in an effort to manage efficiency.

Multiple memory channels may be address-interleaved together to uniformly distribute the memory traffic across memory devices and optimize performance. Using an interleaved traffic protocol, memory data is uniformly distributed across memory devices by assigning addresses to alternating memory channels. Such a technique is commonly referred to as symmetric channel interleaving.

Existing symmetric memory channel interleaving techniques require all of the channels to be activated. For high performance use cases, this is intentional and necessary to achieve the desired level of performance. For low performance use cases, however, this leads to wasted power and inefficiency. Further, performance gains attributable to existing symmetric memory channel interleaving techniques in high performance use cases may sometimes be outweighed by adverse impacts on various parameters associated with a SoC, such as, for example, remaining battery capacity. Also, existing symmetric memory channel interleaving techniques are unable to optimize memory allocations between interleaved and linear zones when system parameters change, leading to inefficient use of memory capacity. Accordingly, there remains a need in the art for improved systems and methods for providing memory channel interleaving.

### SUMMARY OF THE DISCLOSURE

Systems and methods are disclosed for providing dynamic memory channel interleaving in a system on a chip. One such method comprises configuring a memory address map for two or more memory devices accessed via two or more respective memory channels with a plurality of memory zones. The two or more memory devices comprise at least one memory device of a first type and at least one memory device of a second type and the plurality of memory zones comprise at least one high performance memory zone and at least one low power memory zone. Next, a request is received from a process for a virtual memory page, the request comprising a preference for high performance. Also received is one or more system parameter readings, wherein the system parameter readings indicate one or more power management goals in the system on a chip. Based on the system parameter readings, at least one memory device of the first type is selected. Then, based on the preference for high performance, a preferred high performance memory zone within the at least one memory device of the first type is determined and the virtual memory page is assigned to a free physical page in the preferred memory zone.

The exemplary method may further comprise defining a boundary between the preferred memory zone and a low power memory zone using a sliding threshold address in the memory device so that if it is determined that the preferred memory zone requires expansion, the preferred memory zone may be modified accordingly by adjusting the sliding threshold address such that the low power memory zone is reduced. Additionally, the exemplary method may further comprise migrating the virtual memory page from the preferred memory zone within the at least one memory device of the first type to an alternative memory zone so that the at least one memory device of the first type may be powered down in order to reduce the overall power consumption of the system on a chip.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of an embodiment of a system for providing page-by-page memory channel interleaving.

FIG. 2 illustrates an exemplary embodiment of a data table comprising a page-by-page assignment of interleave bits.

FIG. 3 is a flowchart illustrating an embodiment of a method implemented in the system of FIG. 1 for providing page-by-page memory channel interleaving.

FIG. 4a is block diagram illustrating an embodiment of a system memory address map for the memory devices in FIG. 1.

FIG. 4b illustrates the operation of the interleaved and linear blocks in the system memory map of FIG. 4a.

FIG. 5 illustrates a more detailed view of the operation of one of the linear blocks of FIG. 4b.

FIG. 6 illustrates a more detailed view of the operation of one of the interleaved blocks of FIG. 4b.

FIG. 7 is a block/flow diagram illustrating an embodiment of the memory channel interleaver of FIG. 1.

FIG. 8 is a flowchart illustrating an embodiment of a method implemented in the system of FIG. 1 for allocating virtual memory pages to the system memory address map of FIGS. 4a & 4b according to assigned interleave bits.

FIG. 9 illustrates an embodiment of a data table for assigning interleave bits to linear or interleaved memory zones.

FIG. 10 illustrates an exemplary data format for incorporating interleave bits in a first-level translation descriptor of a translation lookaside buffer in the memory management unit of FIG. 1.

FIG. 11 is a flowchart illustrating an embodiment of a method for performing a memory transaction in the system of FIG. 1.

FIG. 12 is a functional block diagram of an embodiment of a system for page-by-page memory channel interleaving using dynamic partial channel interleaving memory management techniques to dynamically adjust, create and modify memory zones based on quality and performance of service (“QPoS”) levels.

FIG. 13 illustrates an embodiment of a data table for assigning pages to linear or interleaved zones according to a sliding threshold address.

FIG. 14A is a block diagram illustrating an embodiment of a system memory address map controlled according to the sliding threshold address.

FIG. 14B is a block diagram illustrating an embodiment of a system memory address map comprising a mixed interleave-linear memory zone.

FIG. 15 is a flowchart illustrating an embodiment of a method implemented in the system of FIG. 15 for allocating memory according to the sliding threshold address.

FIG. 16 is a flowchart illustrating an embodiment of a method 1600 implemented in the system of FIG. 12 for page-by-page memory channel interleaving using dynamic partial channel interleaving memory management techniques to dynamically adjust, create and modify memory zones based on QPoS levels.

FIG. 17 is a block diagram of an embodiment of a portable computer device for incorporating the systems and methods of FIGS. 1-16.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

The term “content” may also include files having executable content, such as: object code, scripts, byte code, markup language files, and patches. In addition, “content” referred to herein, may also include files that are not executable in nature, such as documents that may need to be opened or other data files that need to be accessed.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “communication device,” “wireless device,” “wireless telephone”, “wireless communication device,” and “wireless handset” are used interchangeably. With the advent of third generation (“3G”) wireless technology and four generation (“4G”), greater bandwidth availability has enabled more portable computing devices with a greater variety of wireless capabilities. Therefore, a portable computing device may include a cellular telephone, a pager, a PDA, a smartphone, a navigation device, or a hand-held computer with a wireless connection or link.

Certain multi-channel interleaving techniques provide for efficient bandwidth utilization by uniformly distributing memory transaction traffic across all available memory channels. Under use cases in which high bandwidth is not required to maintain a satisfactory quality of service (“QoS”) level, however, a multi-channel interleaving technique that activates all available memory channels may consume power unnecessarily. Consequently, certain other multi-channel interleaving techniques divide memory space into two or more distinct zones at the time of system boot, one or more for interleaved traffic and one or more for linear traffic. Notably, each of the interleaved zone and the linear zone may be comprised of memory space spanning across multiple memory components accessible by different memory channels. Multi-channel interleaving techniques that leverage such static interleaved and linear memory zones may advantageously reduce power consumption by allocating all transactions associated with high bandwidth applications (i.e., high performance applications) to the interleaved zone while allocating all transactions associated with low bandwidth applications to the linear zone. For example, applications requiring a performance driven QoS may be mapped to the region best positioned to meet the performance requirement at the lowest possible level of power consumption.

Further improved multi-channel interleaving techniques dynamically define interleaved and linear memory zones such that the zones, while initially defined at system boot, may be dynamically rearranged and redefined during runtime on a demand basis and in view of power and performance requirements. Such dynamic partial interleaved memory management techniques may allocate transactions to the zones on a page-by-page basis, thereby avoiding the need to send all transactions of a certain application to a given zone. Depending on the real-time system requirements, dynamic partial channel interleaved techniques may allocate transactions from high performance applications to an interleaved memory zone or, alternatively, may seek to conserve power and allocate transactions from high performance applications to a linear zone, thereby trading performance level for improved power efficiency. It is also envisioned that certain embodiments of a dynamic partial channel interleaved solution may allocate transactions to memory zones that are defined as partially interleaved and partially linear, thereby optimizing the power/performance tradeoff for those applications that do not require the highest performance available through a fully interleaved zone but still require more performance than can be provided through a fully linear zone.

Dynamic partial channel interleaving memory management techniques according to the solution utilize a memory management (“MM”) module in the high level operating system (“HLOS”) that comprises a quality and power of service (“QPoS”) monitor module and a QPoS optimization module. The MM module works to recognize power and/or performance “hints” from the application program interfaces (“API”) while keeping track of current page mappings for transactions coming from the applications. The MM module also monitors system parameters, such as power constraints and remaining battery life, to evaluate the impact of the power and/or performance hints in view of the parameters. For example, an application requesting high performance status for its transactions may be overridden in its request such that the transactions are allocated to a defined memory zone associated with a low power consumption (e.g., a single, low power memory channel accessing a low-power memory component earmarked for linear page transactions).

Embodiments of the solution may define memory zones in association with particular QPoS profiles (quality and power). For example, consider a multi-channel DRAM memory architecture with 4-channels: a given zone might be a linear zone on one of the channels AND/OR a given zone might be a linear zone on two of the channels AND/OR a zone might be an interleaved zone across all four channels AND/OR a zone might be an interleaved zone across a subset of channels AND/OR a zone might be a mixed interleaved-linear zone with an interleaved portion across a subset of channels and a linear portion across a different subset of channels, etc. Also, consider an embodiment of the solution applied within a multi-channel memory with dissimilar memory types: a first zone might be comprised wholly within one of the memory types while a second zone might be defined wholly within a different memory component of a different type. Further, an embodiment of the solution applied within a multi-channel memory with dissimilar memory types may be operable to allocate given transactions to interleaved or linear zones within a given type of the dissimilar memories (i.e., a cascaded approach where the solution uses the system parameters to dictate the memory type and then the particular zone defined within the memory type—a zone within a zone). As would be understood by one of ordinary skill in the art considering the present disclosure, depending on the particular zone defined by an embodiment of the solution the associated QPoS will vary due to channel power consumption, memory device power consumption, interleaving/linear write protocol, etc.

Essentially, the monitor module receives the performance/power hints from the APIs and monitors the system parameters. Based on the system parameters, the optimization module decides how to allocate pages in the memory architecture based on QPoS tradeoff balancing. Further, the optimization module may dynamically adjust defined memory zones and/or define new memory zones in an effort to optimize the QPoS tradeoffs. For example, if power conservation is not a priority based on the system parameters, and a demand for high performance transactions from the applications exceeds the capacity of memory zones associated with high performance, the optimization module may dynamically adjust the zones such that more memory capacity is earmarked for high performance transactions.

It is also envisioned that embodiments of the solution for dynamic rearrangement of interleaved and linear memory zones may form multiple zones, each zone associated with a particular QPoS performance level. Certain zones may be in a linear zone of the memory devices while certain other zones are formed within the interleaved zones. Certain other zones may be of a mixed interleaved-linear configuration in order to provide an intermediate QPoS performance level not otherwise achievable in an all-interleaved or all-linear zone. Further, interleaved zones may be spread across all available memory channels or may be spread across a subset of available memory channels.

Advantageously, embodiments of the solution may work to dynamically allocate and free virtual memory addresses from any formed zone based on monitored parameters useful for estimating QPoS tradeoffs. For example, embodiments may assign transactions to zones with the lowest power level capable of supporting a required performance for page allocations. Moreover, embodiments may assign transactions without a request for high performance to the low power zone having the lowest power level of the various lower performance zones. Further, embodiments may assign transactions with a request for high performance to a high performance zone without regard for power consumption.

It is envisioned that certain embodiments may recognize a preferred zone for allocation of certain transactions in addition to “fallback” zones suitable for allocation of the same transactions in the event that the preferred zone is not available or optimal. Certain embodiments may seek to audit and migrate or evict pages from a “power hungry” but higher performance memory zone to a zone with a more optimal QPoS level for the given application associated with the pages. In this way, embodiments of the solution may migrate pages to a memory zone that results in a power savings without detrimentally impacting the QoS provided by the associated application. For example, an evicted page may be the last page active in a given DRAM channel and, therefore, by evicting the page to a memory device hosting a zone with a similar QPoS level and accessed by a different channel, the original DRAM channel may be powered down.

An advantage of embodiments of the solution is to optimize memory related power consumption for a given performance requirement. Essentially, if transactions may be serviced more efficiently (in terms of power consumption) in one memory zone than in another memory zone, then embodiments of the solution may allocate transactions to the more efficient zone and/or create a more efficient zone to service the allocations and/or increase the capacity of the more efficient zone and/or migrate pages to the more efficient zone.

The monitor module tracks the current page allocations in the interleaved zones (whether across all channels or a subset of channels) and the linear zones and the mixed zones. The optimization module works to dynamically rearrange the interleaved and/or linear zones and/or mixed zones within and across the memory devices to create new zones of QPoS levels available for incoming paged allocation based on the needs detected by the monitor module through QPoS hints (from the APIs) and current power/performance states in the memory devices. Based on the QPoS requirements of a given application, or the monitored system parameters, the optimization module determines a memory zone for the allocations. For example, in the case of an interleaved zone formed from a subset of channels (e.g., two channels out of four available channels), the memory management module may dictate that the two unused channels decline being refreshed in order to conserve power. As a further example, in the event that no applications require a QPoS level provided by an interleaved zone accessed by all available channels, the optimization module may continue to allocate transactions to an interleaved zone accessed by a subset of available channels while the remaining channels are powered down to conserve power.

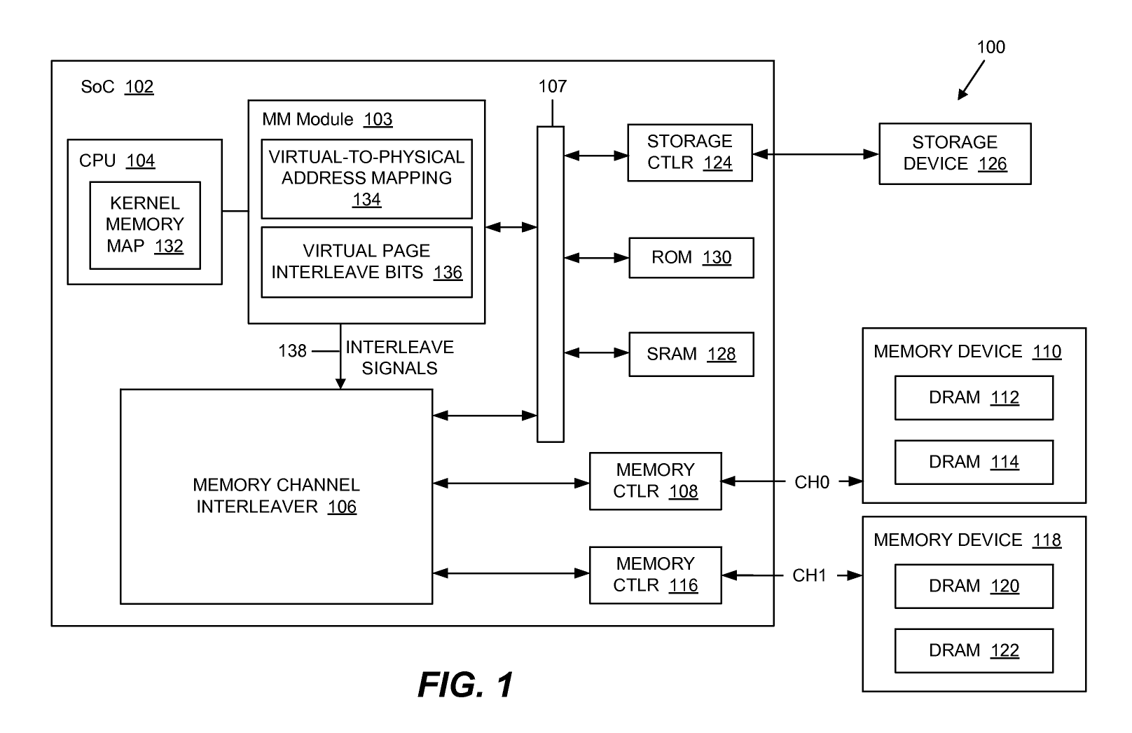

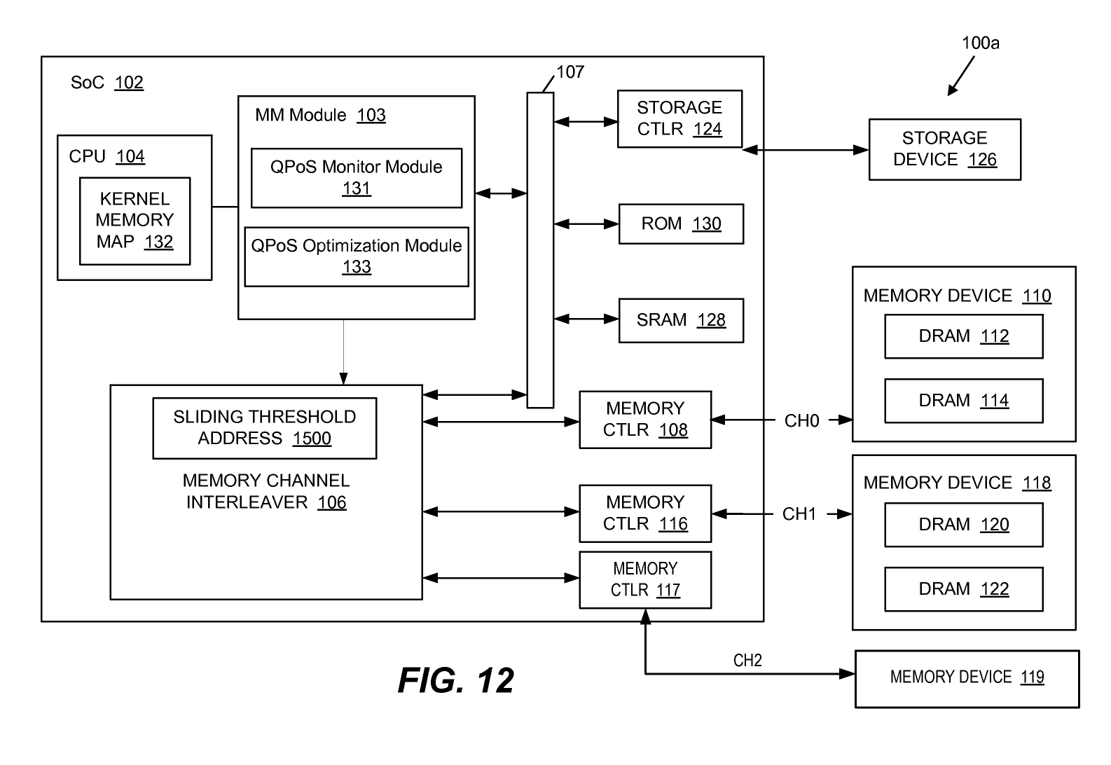

FIGS. 1-11 collectively illustrate systems and methods for defining memory zones within memory devices and across memory channels and allocating pages to the appropriate zones based on “hints” or power/performance preferences associated with the applications making the memory transaction requests. The systems and methods described and illustrated relative to FIGS. 1-11 may be used by embodiments of the solution that work to adjust, create and modify the memory zones in view of QPoS considerations. Embodiments of the solution that work to adjust, create and modify the memory zones in view of QPoS considerations, in addition to employing the methodologies described relative to FIGS. 1-11 to allocate pages to the memory zones, will be described in FIGS. 12-16.

FIG. 1 illustrates a system 100 for providing memory channel interleaving with selective performance or power optimization. The system 100 may be implemented in any computing device, including a personal computer, a workstation, a server, a portable computing device (“PCD”), such as a cellular telephone, a portable digital assistant (“PDA”), a portable game console, a palmtop computer, or a tablet computer.

As illustrated in the embodiment of FIG. 1, the system 100 comprises a system on chip (“SoC”) 102 comprising various on-chip components and various external components connected to the SoC 102. The SoC 102 comprises one or more processing units, a memory management (“MM”) module 103, a memory channel interleaver 106, a storage controller 124, and on-board memory (e.g., a static random access memory (“SRAM”) 128, read only memory (“ROM”) 130, etc.) interconnected by a SoC bus 107. The storage controller 124 may be electrically connected to and communicate with an external storage device 126. The memory channel interleaver 106 receives read/write memory requests associated with the CPU 104 (or other memory clients) and distributes the memory data between two or more memory controllers 108, 116, which are connected to respective external memory devices 110, 118 via a dedicated memory channel (CH0 and CH1, respectively). In the example of FIG. 1, the system 100 comprises two memory devices 110 and 118. The memory device 110 is connected to the memory controller 108 and communicates via a first memory channel (CH0). The memory device 118 is connected to the memory controller 116 and communicates via a second memory channel (CH1).

It should be appreciated that any number of memory devices, memory controllers, and memory channels may be used in the system 100 with any desirable types, sizes, and configurations of memory (e.g., double data rate (DDR) memory). In the embodiment of FIG. 1, the memory device 110 supported via channel CH0 comprises two dynamic random access memory (“DRAM”) devices: a DRAM 112 and a DRAM 114. The memory device 118 supported via channel CH1 also comprises two DRAM devices: a DRAM 120 and a DRAM 122.

As described below in more detail, the system 100 provides page-by-page memory channel interleaving based on static, predefined memory zones. An operating system (O/S) executing on the CPU 104 may employ the MM module 103 on a page-by-page basis to determine whether each page being requested by memory clients from the memory devices 110 and 118 are to be interleaved or mapped in a linear manner. When making requests for virtual memory pages, processes may specify a preference for either interleaved memory or linear memory. The preferences may be specified in real-time and on a page-by-page basis for any memory allocation request. As would be understood by one of ordinary skill in the art, a preference for interleaved memory may be associated with a high performance use case while a preference for linear memory may be associated with a low power use case.

In an embodiment, the system 100 may control page-by-page memory channel interleaving via the kernel memory map 132, the MM module 103, and the memory channel interleaver 106. It should be appreciated that herein the term “page” refers to a memory page or a virtual page comprising a fixed-length contiguous block of virtual memory, which may be described by a single entry in a page table. In this manner, the page size (e.g., 4 kbytes) comprises the smallest unit of data for memory management in an exemplary virtual memory operating system. To facilitate page-by-page memory channel interleaving, the kernel memory map 132 may comprise data for keeping track of whether pages are assigned to interleaved or linear memory.

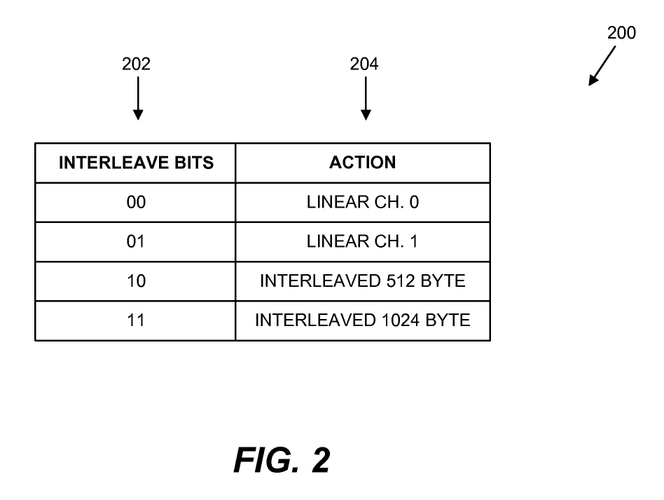

As illustrated in the exemplary table 200 of FIG. 2, the kernel memory map 132 may comprise a 2-bit interleave field 202. Each combination of interleave bits may be used to define a corresponding control action (column 204). The interleave bits may specify whether the corresponding page is to be assigned to one or more linear zones or one or more interleaved zones. In the example of FIG. 2, if the interleave bits are “00”, the corresponding page may be assigned to a first linear channel (CH. 0). If the interleave bits are “01”, the corresponding page may be assigned to a second linear channel (CH. 1). If the interleave bits are “10”, the corresponding page may be assigned to a first interleaved zone (e.g., 512 bytes). If the interleave bits are “11”, the corresponding page may be assigned to a second interleaved zone (e.g., 1024 bytes). It should be appreciated that the interleave field 202 and the corresponding actions may be modified to accommodate various alternative schemes, actions, number of bits, etc.

The interleave bits may be added to a translation table entry and decoded by the MM module 103. As further illustrated in FIG. 1, the MM module 103 may comprise a virtual page interleave bits block 136, which decodes the interleave bits. For every memory access, the associated interleave bits may be assigned to the corresponding page. The MM module 103 may send the interleave bits via interleave signals 138 to the memory channel interleaver 106, which then performs channel interleaving based upon their value. As known in the art, the MM module 103 may comprise logic and storage (e.g., cache) for performing virtual-to-physical address mapping (block 134).

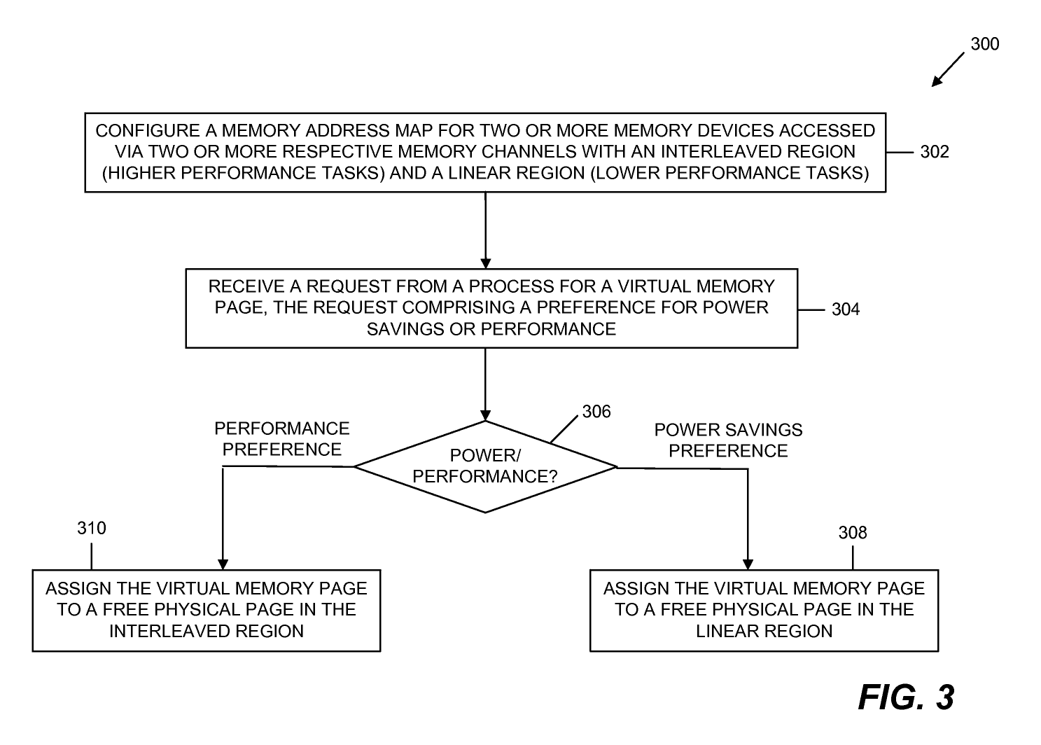

FIG. 3 illustrates an embodiment of a method 300 implemented by the system 100 for providing page-by-page memory channel interleaving. At block 302, a memory address map is configured for two or more memory devices accessed via two or more respective memory channels. A first memory device 110 may be accessed via a first memory channel (CH0). A second memory device 118 may be accessed via a second memory channel (CH1). The memory address map is configured with one or more interleaved zones for performing relatively higher performance tasks and one or more linear zones for performing relatively lower performance tasks.

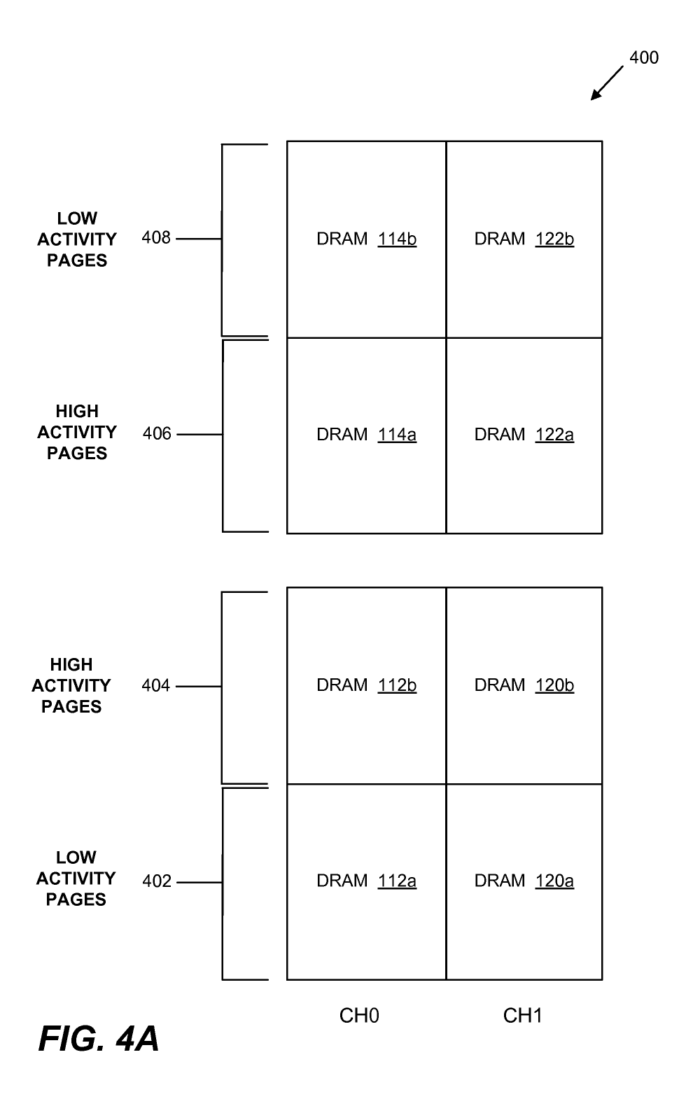

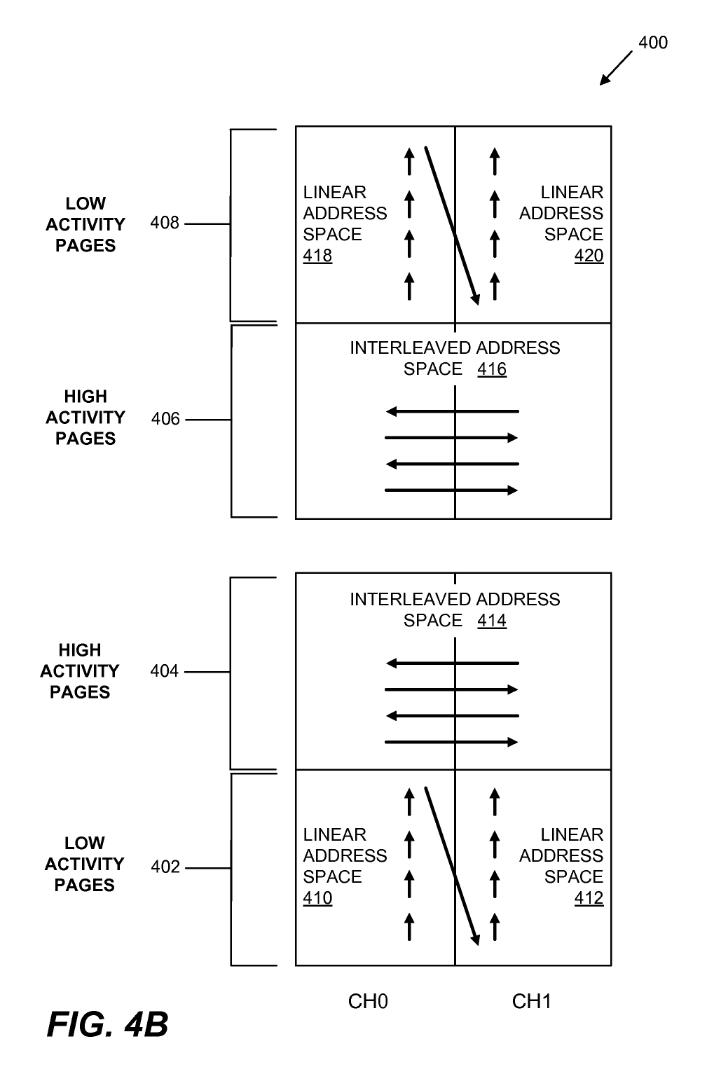

An exemplary implementation of the memory address map is described below with respect to FIGS. 4A, 4B, 5, and 6. At block 304, a request is received from a process executing on a processing device (e.g., CPU 104) for a virtual memory page. The request may specify a preference, hint, or other information for indicating whether the process prefers to use interleaved or non-interleaved (i.e., linear) memory. The request may be received or otherwise provided to the MM module 103 (or other components) for processing, decoding, and assignment. At decision block 306, if the preference is for performance (e.g., high activity pages), the virtual memory page may be assigned to a free physical page in an interleaved zone (block 310). If the preference is for power savings (e.g., low activity pages), the virtual memory page may be assigned to a free physical page in a non-interleaved or linear zone (block 308).

FIG. 4A illustrates an exemplary embodiment of a memory address map 400 for the system memory comprising memory devices 110 and 118. As illustrated in FIG. 1, memory device 110 comprises DRAM 112 and DRAM 114. Memory device 118 comprises DRAM 120 and DRAM 122. The system memory may be divided into fixed-size macro blocks of memory. In an embodiment, each macro block comprises 128 MBytes. Each macro block uses the same interleave type (e.g., interleaved 512 bytes, interleaved 1024 bytes, non-interleaved or linear, etc.). Unused memory are not assigned an interleave type.

As illustrated in FIGS. 4A and 4B, the system memory comprises linear zones 402 and 408 and interleaved zones 404 and 406. The linear zones 402 and 408 may be used for relatively low power use cases and/or tasks, and the interleaved zones 404 and 406 may be used for relatively high performance use cases and/or tasks. Each zone comprises a separate allocated memory address space with a corresponding address range divided between the two memory channels CH0 and CH1. The interleaved zones comprise an interleaved address space, and the linear zones comprise a linear address space.

Linear zone 402 comprises a first portion of DRAM 112 (112a) and a first portion of DRAM 120 (120a). DRAM portion 112a defines a linear address space 410 for CH. 0. DRAM 120a defines a linear address space 412 for CH. 1. Interleaved zone 404 comprises a second portion of DRAM 112 (112b) and a second portion of DRAM 120 (120b), which defines an interleaved address space 414. In a similar manner, linear zone 408 comprises a first portion of DRAM 114 (114b) and a first portion of DRAM 122 (122b). DRAM portion 114b defines a linear address space 418 for CH0. DRAM 122b defines a linear address space 420 for CH1. Interleaved zone 406 comprises a second portion of DRAM 114 (114a) and a second portion of DRAM 122 (122a), which defines an interleaved address space 416.

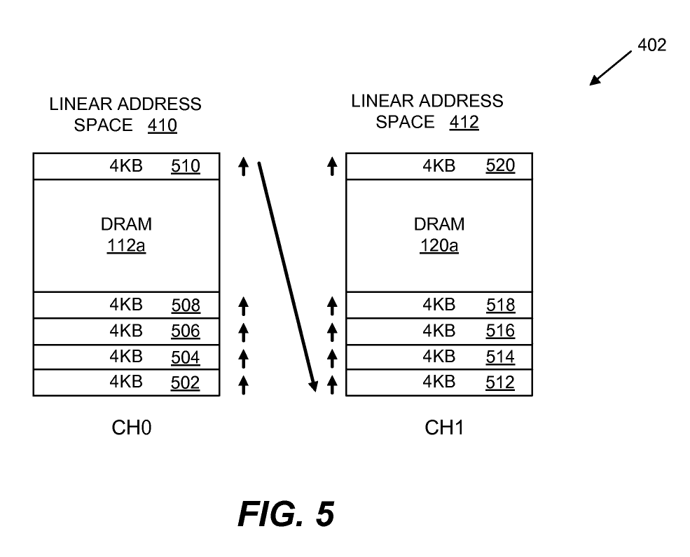

FIG. 5 illustrates a more detailed view of the operation of the linear zone 402. The linear zone 402 comprises separate consecutive memory address ranges within the same channel. A first range of consecutive memory addresses (represented by numerals 502, 504, 506, 508, and 510) may be assigned to DRAM 112a in CH0. A second range of consecutive addresses (represented by numerals 512, 514, 516, 518, and 520) may be assigned to DRAM 120a in CH1. After the last address 510 in DRAM 112a is used, the first address 512 in DRAM 120a may be used. The vertical arrows illustrate that the consecutive addresses are assigned within CH0 until a top or last address in DRAM 112a is reached (address 510). When the last available address in CH0 is reached, the next address may be assigned to the first address 512. Then, the allocation scheme follows the consecutive memory addresses in CH1 until a top address is reached (address 520).

In this manner, it should be appreciated that low performance use case data may be contained completely in either channel CH0 or channel CH1. In operation, only one of the channels CH0 and CH1 may be active while the other channel is placed in an inactive or “self-refresh” mode to conserve memory power. This can be extended to any number N memory channels.

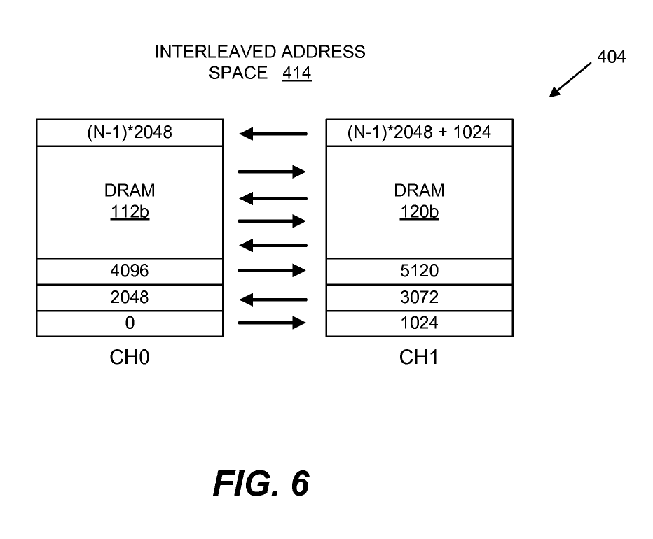

FIG. 6 illustrates a more detailed view of the operation of the interleaved zone 404 (interleaved address space 414). In operation, a first address (address 0) may be assigned to a lower address associated with DRAM 112b and memory channel CH0. The next address in the interleaved address range (address 32) may be assigned to a lower address associated with DRAM 120b and memory channel CH1. In this manner, a pattern of alternating addresses may be “striped” or interleaved across memory channels CH0 and CH1, ascending to top or last addresses associated with DRAM 112b and 120b. The horizontal arrows between channels CH0 and CH1 illustrate how the addresses “ping-pong” between the memory channels. Clients requesting virtual pages (e.g., CPU 104) for reading/writing data to the memory devices may be serviced by both memory channels CH0 and CH1 because the data addresses may be assumed to be random and, therefore, may be uniformly distributed across both channels CH0 and CH1.

In an embodiment, the memory channel interleaver 106 (FIG. 1) may be configured to resolve and perform the interleave type for any macro block in the system memory. A memory allocator may keep track of the interleave types using the interleave bit field 202 (FIG. 2) for each page. The memory allocator may keep track of free pages or holes in all used macro blocks. Memory allocation requests may be fulfilled using free pages from the requested interleave type, as described above. Unused macro blocks may be created for any interleave type, as needed during operation of the system 100. Allocations for a linear type from different processes may attempt to load balance across available channels (e.g., CH0 or CH1). This may minimize performance degradation that could occur if one linear channel needs to service different bandwidth compared to another linear channel. In another embodiment, performance may be balanced using a token tracking scheme.

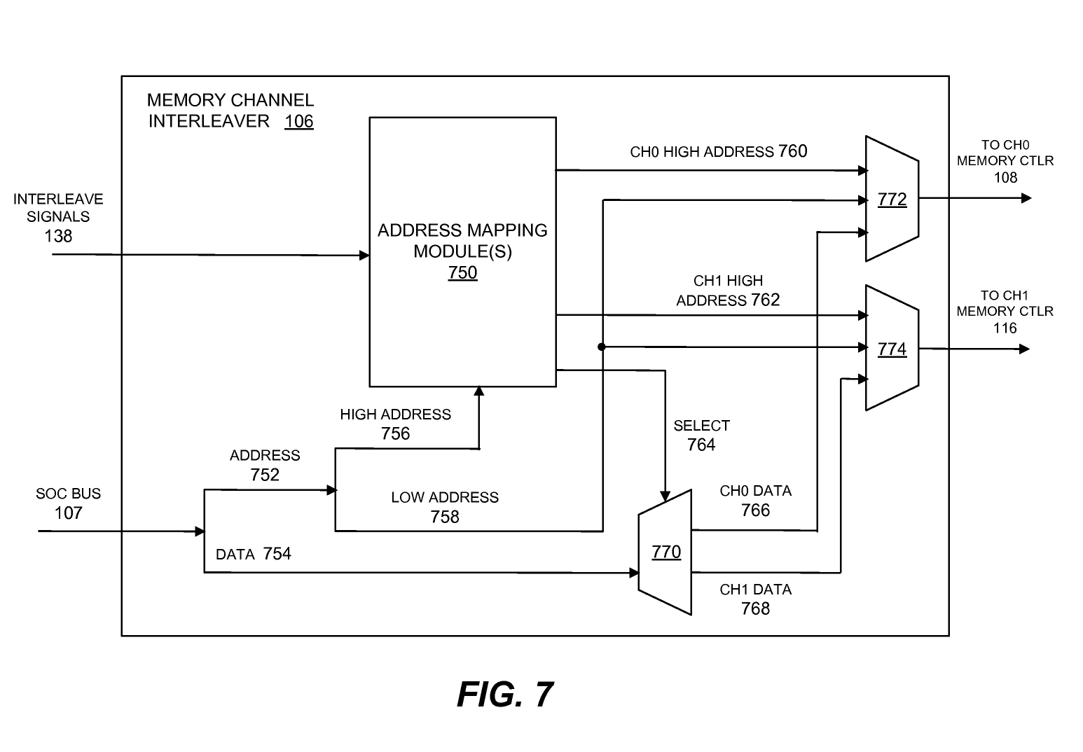

FIG. 7 is a schematic/flow diagram illustrating the architecture, operation, and/or functionality of an embodiment of the memory channel interleaver 106. The memory channel interleaver 106 receives the interleave signals 138 from MM module 103 and input on the SoC bus 107. The memory channel interleaver 106 provides outputs to memory controllers 108 and 116 (memory channels CH0 and CH1, respectively) via separate memory controller buses. The memory controller buses may run at half the rate of the SoC bus 107 with the net data throughput being matched. Address mapping module(s) 750 may be programmed via the SoC bus 107. The address mapping module(s) 750 may configure and access the address memory map 400, as described above, with the linear zones 402 and 408 and the interleaved zone 404 and 406.

The interleave signals 138 received from the MM module 103 signal that the current write or read transaction on SoC bus 107 is, for example, linear, interleaved every 512 byte addresses, or interleaved every 1024 byte addresses. Address mapping is controlled via the interleave signals 138, which takes the high address bits 756 and maps them to CH0 and CH1 high addresses 760 and 762. Data traffic entering on the SoC bus 107 is routed to a data selector 770, which forwards the data to memory controllers 108 and 116 via merge components 772 and 774, respectively, based on a select signal 764 provided by the address mapping module(s) 750. For each traffic packet, a high address 756 enters the address mapping module(s) 750. The address mapping module(s) 750 generates the output interleaved signals 760, 762, and 764 based on the value of the interleave signals 138. The select signal 764 specifies whether CH0 or CH1 has been selected. The merge components 772 and 774 may comprise a recombining of the high addresses 760 and 762, low address 705, and the CH0 data 766 and the CH1 data 768.

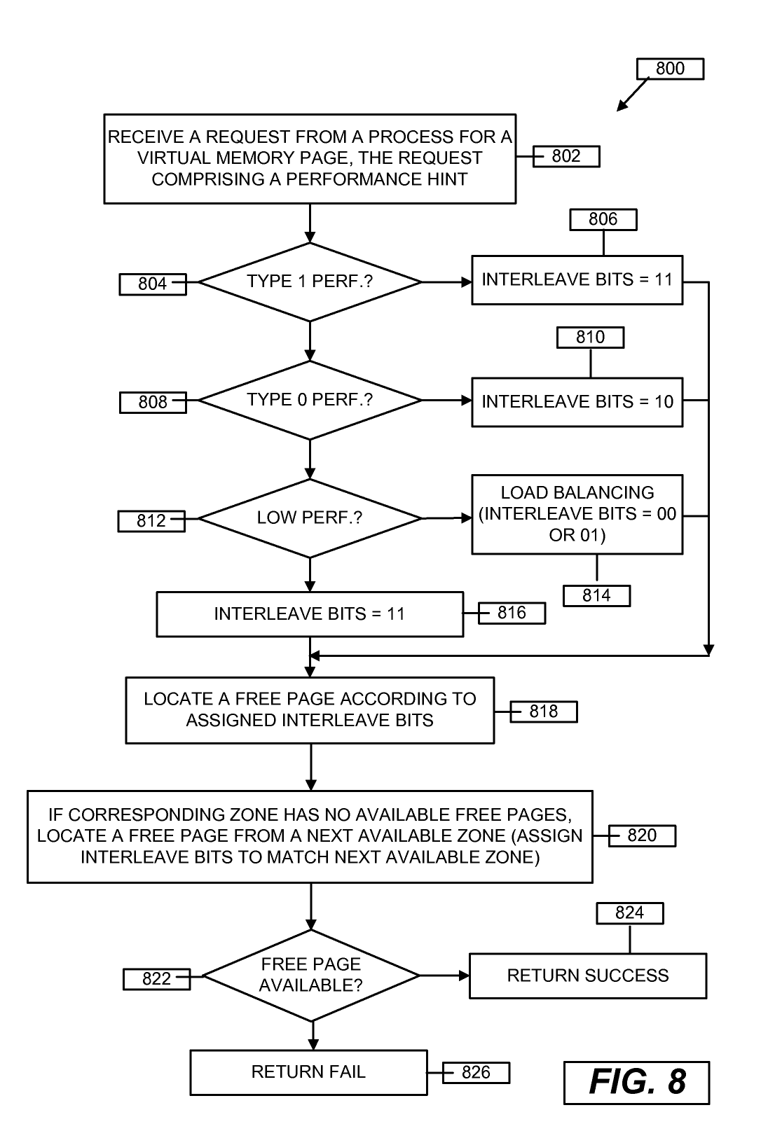

FIG. 8 illustrates an embodiment of a method 800 for allocating memory in the system 100. In an embodiment, the O/S, the MM module 103, other components in the system 100, or any combination thereof may implement aspects of the method 800. At block 802, a request is received from a process for a virtual memory page. As described above, the request may comprise a performance hint. If the performance hint corresponds to a first performance type 1 (decision block 804), the interleave bits may be assigned a value “11” (block 806). If the performance hint corresponds to a second performance type 0 (decision block 808), the interleave bits may be assigned a value “10” (block 810). If the performance hint corresponds to a low performance (decision block 812), the interleave bits may be assigned a value “00” (block 814). At block 816, the interleave bits may be assigned a value “11” as either a default value or in the event that a performance hint is not provided by the process requesting the virtual memory page.

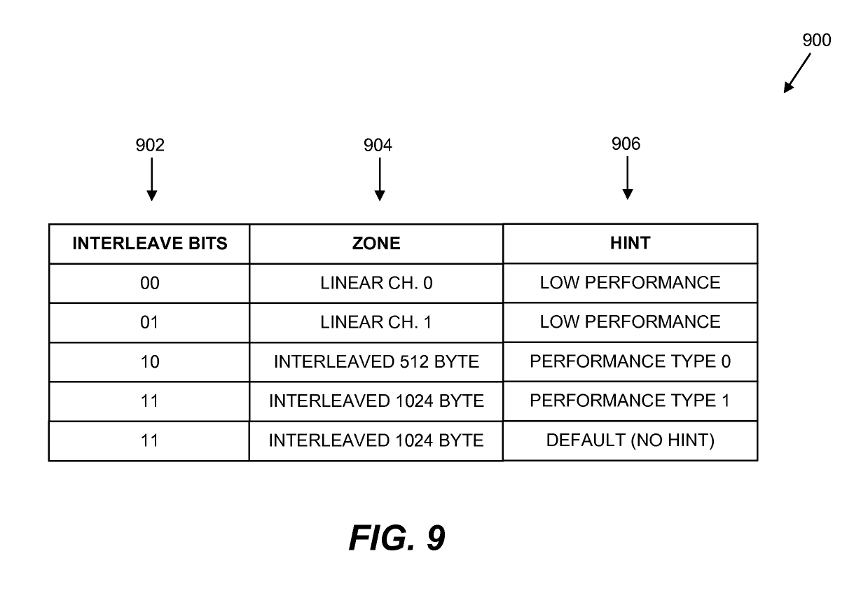

FIG. 9 illustrates an embodiment of a data table 900 for assigning the interleave bits (field 902) based on various performance hints (field 906). The interleave bits (field 902) defines the corresponding memory zones (field 904) as either linear CH0, linear CH1, interleaved type 0 (every 512 bytes), or interleaved type 1 (every 1024 bytes). In this manner, the received performance hint may be translated to an appropriate memory zone.

Referring again to FIG. 8, at block 818, a free physical page is located in the appropriate memory zone according to the assigned interleave bits. If a corresponding memory zone does not have an available free page, a free page may be located from a next available memory zone, at block 820, of a lower type. The interleave bits may be assigned to match the next available memory zone. If a free page is not available (decision block 822), the method 800 may return a fail (block 826). If a free page is available, the method 800 may return a success (block 824).

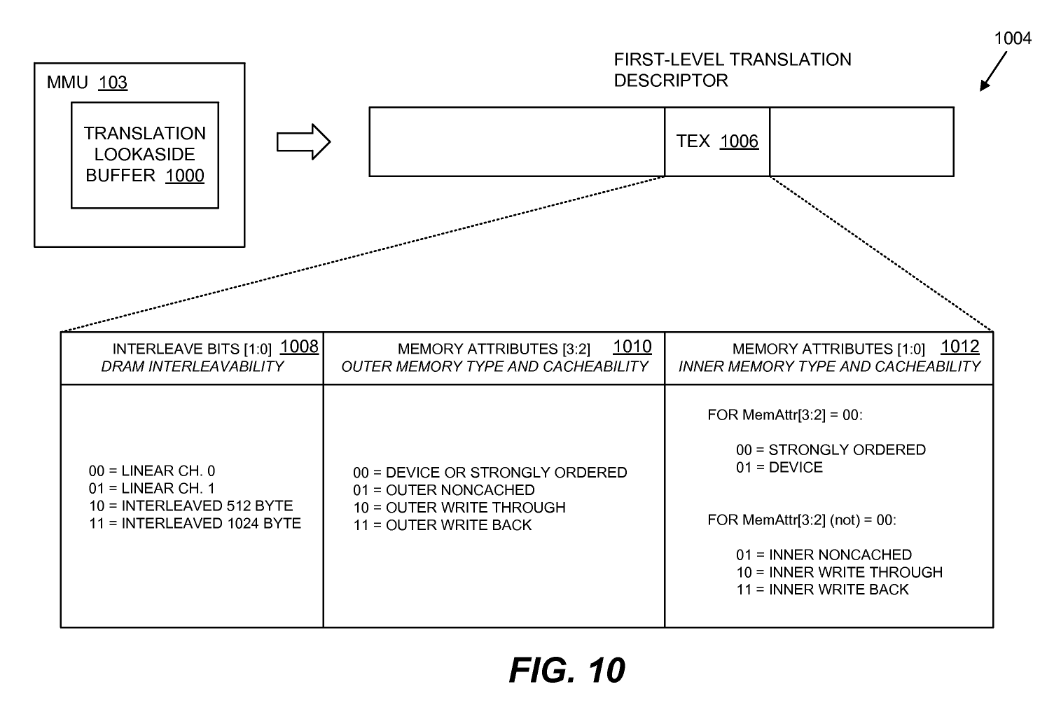

As mentioned above, the O/S kernel running on CPU 104 may cooperate in managing the performance/interleave type for each memory allocation via the kernel memory map 132. To facilitate fast translation and caching, this information may be implemented in a page descriptor of a translation lookaside buffer 1000 in MM module 103. FIG. 10 illustrates an exemplary data format for incorporating the interleave bits in a first-level translation descriptor 1004 of the translation lookaside buffer 1000. The interleave bits may be added to a type exchange (TEX) field 1006 in the first-level translation descriptor 1004. As illustrated in FIG. 10, the TEX field 1006 may comprise sub-fields 1008, 1010, and 1012. Sub-field 1008 defines the interleave bits. Sub-field 1010 defines data related to memory attributes for an outer memory type and cacheability. Sub-field 1012 defines data related to memory attributes for an inner memory type and cacheability. The interleave bits provided in sub-field 1008 may be propagated downstream to the memory channel interleaver 106.

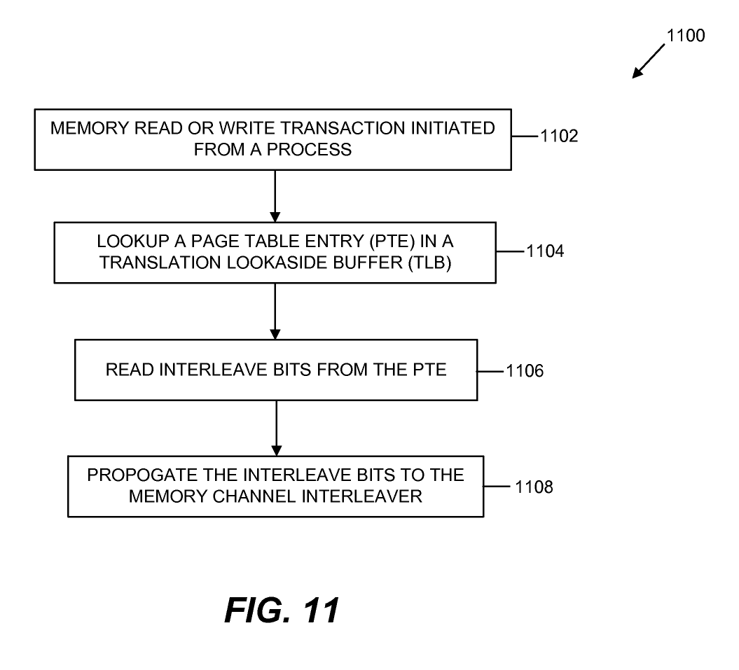

FIG. 11 is a flowchart illustrating an embodiment of a method 1100 comprising actions taken by the translation lookaside buffer 1000 and the memory channel interleaver 106 whenever a process performs a write or read to the memory devices 110 and 118. At block 1102, a memory read or write transaction is initiated from a process executing on CPU 104 or any other processing device. At block 1104, the page table entry is looked up in the translation lookaside buffer 1000. The interleave bits are read from the page table entry (block 1106), and propagated to the memory channel interleaver 106.

Referring to FIGS. 12-16, another embodiment of the system 100 will be described. In this embodiment, the system 100 provides page-by-page memory channel interleaving using dynamic partial channel interleaving memory management techniques. Embodiments dynamically adjust, create and modify memory zones based on quality and performance of service levels (“QPoS”) requested by applications and required by the SoC to achieve power management goals.

FIG. 12 is a functional block diagram of an embodiment of a system 100a for page-by-page memory channel interleaving using dynamic partial channel interleaving memory management techniques to dynamically adjust, create and modify memory zones based on QPoS levels. The functionality of the system 100 described relative to FIG. 1 is also envisioned for the system 100a embodiment. That is, using the memory map 132, the MM module 103 works with the memory channel interleaver 106 to allocate memory transactions from processes or applications to the memory devices 110, 118. The MM module 103 and the memory channel interleaver 106 work to define memory zones, either interleaved or linear, or a mixed interleaved-linear configuration, across one or more of the memory channels CH0, CH1 and memory devices 110, 118. Based on the QPoS requirement indicated by a given transaction and/or associated with an application that issued the given transaction, the MM module 103 and memory channel interleaver 106 allocate transactions to the particular defined memory zones which are best positioned to provide the needed QPoS.

Notably, in the system 100a, the MM module 103 further comprises a QPoS monitor module 131 and a QPoS optimization module 133. Advantageously, the monitor module 131 and the optimization module 133 not only recognize QPoS “hints” or preferences from an API associated with an application running on a processing component (e.g., CPU 104), but also monitor and weigh various parameters of the SoC 102 that indicate restraints, or lack thereof, on power consumption. In this way, the monitor module 131 and the optimization module 133 may recognize that power management goals across the SoC 102 may override the QPoS preference of any given application or individual memory transaction.

The monitor module 131, in addition to recognizing QPoS hints from applications and/or individual memory transactions, may actively monitor system parameters such as, but not limited to, operating temperatures, ambient temperatures, remaining battery capacity, aggregate power usage, etc. and provide the data to the optimization module 133. The optimization module may use the data monitored and provided by the monitor module 131 to balance the need for power efficiency against the performance preferences of the application(s). If the optimization module 133 determines that the temperature of the SoC 102 is dictating a reduction in power consumption, for example, then the optimization module 133 may override a high QPoS preference for a high performance QPoS memory zone (e.g., an interleaved zone) and allocate the transaction to a low power QPoS memory zone (e.g., a linear zone).

Using the data from the monitor module 131, it is envisioned that the optimization module 133 may dynamically adjust and/or create memory zones in the memory devices 110, 118, 119 and across memory channels CH0, CH1 or CH2 via memory controllers 108, 116 and 117, respectively. In the system 100a, the memory devices 110, 118 are of a common type while the memory device 119 is of a dissimilar type. As such, the optimization module 133 may use the monitored parameters and API hints to first select a memory type that is best suited for providing a required QPoS level to a requesting application without overconsumption of power and, subsequently, select a defined memory zone within the selected memory type that may most closely provides the desired QPoS level.

It is further envisioned that the optimization module 133 may use the monitored parameters and the API hints to trigger adjust, modification and/or creation of memory zones. For example, if the optimization module recognizes that there are no restrictions on power consumption within the SoC 102, and that the requested transaction includes a preference for a high performance memory zone, and that a high performance interleaved zone defined across memory devices 110, 118 is low in available capacity, and that a relatively large linear zone in the memory devices 110, 118 is underutilized, the optimization module may work to reduce the allocated memory space of the linear zone in favor of reallocating the space to the high performance interleaved zone. In this way, embodiments of the system and method may dynamically adjust memory zones defined within and across the devices 110, 118, 119 and channels CH0, CH1, CH2 to optimize memory usage in view of system power considerations and application performance preferences.

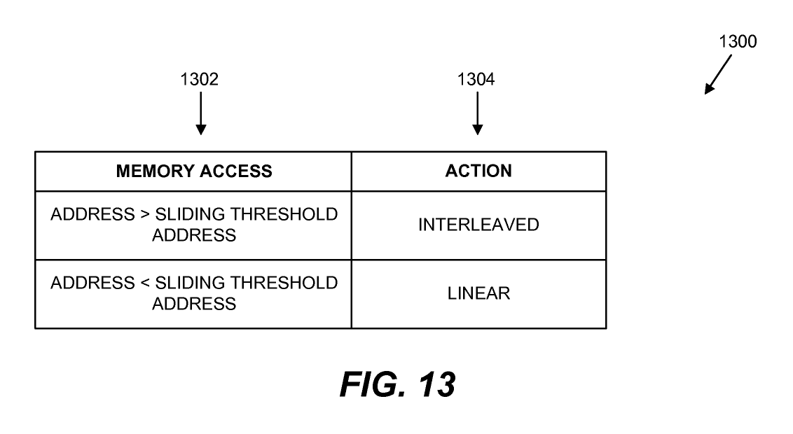

FIG. 13 illustrates an embodiment of a data table for assigning pages to linear or interleaved zones according to a sliding threshold address. The illustrations in FIGS. 13-15 provide a method that may be implemented by an optimization module 133 to adjust, create or modify memory zones defined within and across memory devices of similar and dissimilar types and accessed by different memory channels.

As illustrated in FIG. 13, memory access to interleaved or linear memory may be controlled, on a page-by-page basis, according to the sliding threshold address. In an embodiment, if the requested memory address is greater than the sliding threshold address (column 1302), the system 100a may assign the request to interleaved memory (column 1304). If the requested memory address is less than the sliding threshold address, the system 100a may assign the request to linear memory.

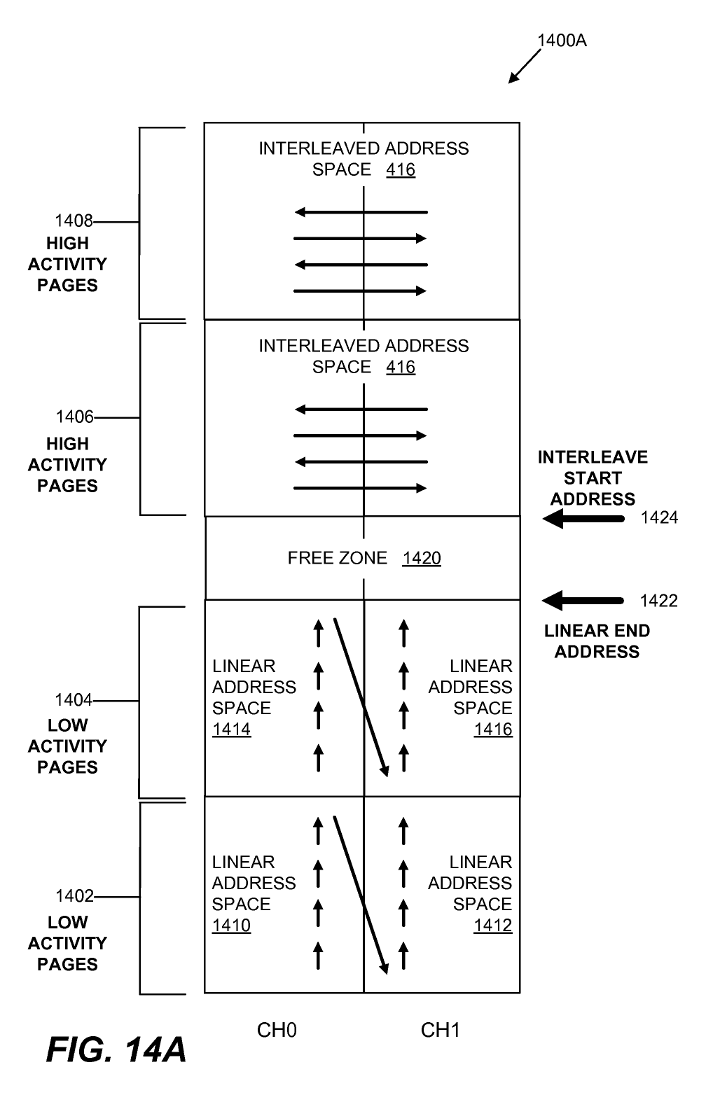

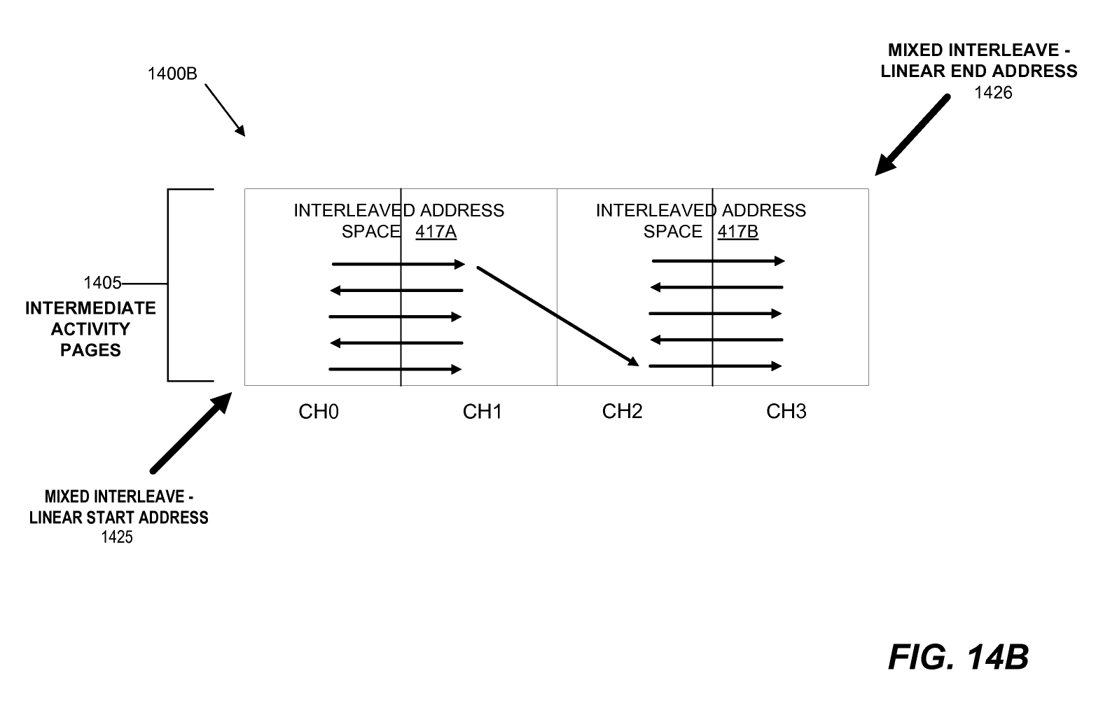

FIG. 14A illustrates an exemplary embodiment of a memory address map 1400A, which comprises a sliding threshold address for enabling page-by-page channel interleaving. Notably, although the exemplary memory address map 1400A is shown and described within the context of memory devices 110, 118 in FIG. 12 (accessible by memory channels CH0 and CH1, respectively), it will be understood that an optimization module 133 within a given embodiment of the solution may apply similar methodologies for adjusting, creating and modifying memory zones in and across dissimilar memory types. In this way, embodiments of the solution may provide memory zones well suited for delivering a required performance level without unnecessarily burdening power supplies.

Returning to the FIG. 14A illustration, memory address map 1400A may comprise linear macro blocks 1402 and 1404 and interleaved macro blocks 1406 and 1408. Linear macro block 1402 comprises a linear address space 1410 for CH0 and a linear address space 1412 for CH1. Linear macro block 1404 comprises a linear address space 1414 for CH0 and a linear address space 1416 for CH1. Interleaved macro blocks 1406 and 1408 comprise respective interleaved address spaces 416.

As further illustrated in FIG. 14A, the sliding threshold address may define a boundary between linear macro block 1404 and interleaved macro block 1406. In an embodiment, the sliding threshold specifies a linear end address 1422 and an interleave start address 1424. The linear end address 1422 comprises the last address in the linear address space 1416 of linear macro block 1404. The interleaved start address 1424 comprises the first address in the interleaved address space corresponding to interleaved macro block 1406. A free zone 1420 between addresses 1422 and 1424 may comprise unused memory, which may be available for allocation to further linear or interleaved macro blocks. It should be appreciated that the system 100 may adjust the sliding threshold up or down as additional macro blocks are created. The optimization module 133 may control the adjustment of the sliding threshold.

When freeing memory, unused macro blocks may be relocated into the free zone 1420. This may reduce latency when adjusting the sliding threshold. The optimization module 133, working with the monitor module 131, may keep track of free pages or holes in all used macro blocks. Memory allocation requests may be fulfilled using free pages from the requested interleave type.

FIG. 14B is a block diagram illustrating an embodiment of a system memory address map 1400B comprising a mixed interleave-linear memory zone. In the FIG. 14B illustration, memory address map 1400B comprises a mixed interleave-linear macro block 1405 that may be suitable for delivering an intermediate QPoS to an application requiring an intermediate level of performance. Mixed interleave-linear macro block 1405 comprises an interleaved address space 417A for channels CH0 and CH1 and an interleaved address space 417B for channels CH2 and CH3. Transactions may be written in an interleaved manner to the exemplary macro block 1405 beginning at start address 1425 and via two channels CH0 and CH1. Once address space 417A is “full,” the transaction may continue to address space 417B, which is also a part of the mixed zone 1405, until end address 1426 is reached. Advantageously, when the optimization module 133 switches the transaction over to space 416B (which is accessed via channels CH2 and CH3), the channels CH0 and CH1 may be powered down. In this way, the application with which the transaction is associated will continue to receive an intermediate QPoS level as may be delivered by a dual channel interleaved memory while channels CH0 and/or CH1 are freed up for other transactions or powered down.

Notably, the sliding threshold address described in FIG. 14A may be used to define a boundary between mixed interleave-linear macro block 1405 and other macro blocks. Similarly, the free zone 1420 described in FIG. 14A may be leveraged to allocate unused memory to/from the mixed interleave-linear macro block 1405. It should be appreciated that FIG. 14B is an exemplary illustration of a mixed interleave-linear memory zone and is not meant to suggest that a mixed interleave-linear memory zone is limited to complimentary dual-channel interleaved address spaces. For example, it is envisioned that an embodiment of the solution may leverage multiple forms/configurations of interleaved (i.e., mixed interleaved-linear) regions, each with different power/performance mappings. A mixed interleave-linear region may provide a bit more performance than an all-linear zone, and lower power consumption than the most performance driven interleaved zone.

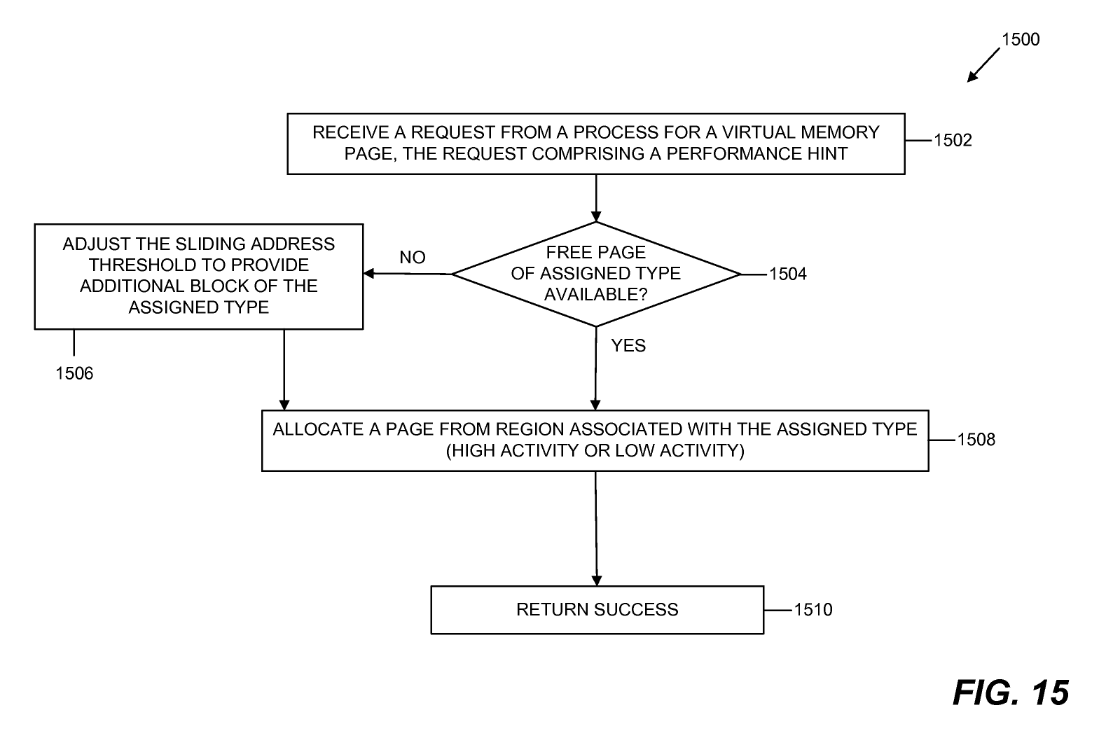

FIG. 15 is a flowchart illustrating an embodiment of a method 1500 implemented in the system of FIG. 12 for allocating memory according to the sliding threshold address. At block 1502, a request is received from a process for a virtual memory page. As described above, the request may comprise a performance hint and/or a power hint. If a free page of the assigned type (interleaved or linear) is available (decision block 1504), a page may be allocated from the zone associated with the assigned type (interleaved or linear). If a free page of the assigned type is not available, the sliding threshold address may be adjusted to providing an additional macro block of the assigned type. At block 1510, the method may return a success indicator (block 1510). If the request contains only a performance hint, it is envisioned that the memory region allocated may be the lowest power consumption zone available and capable of providing the requested performance.

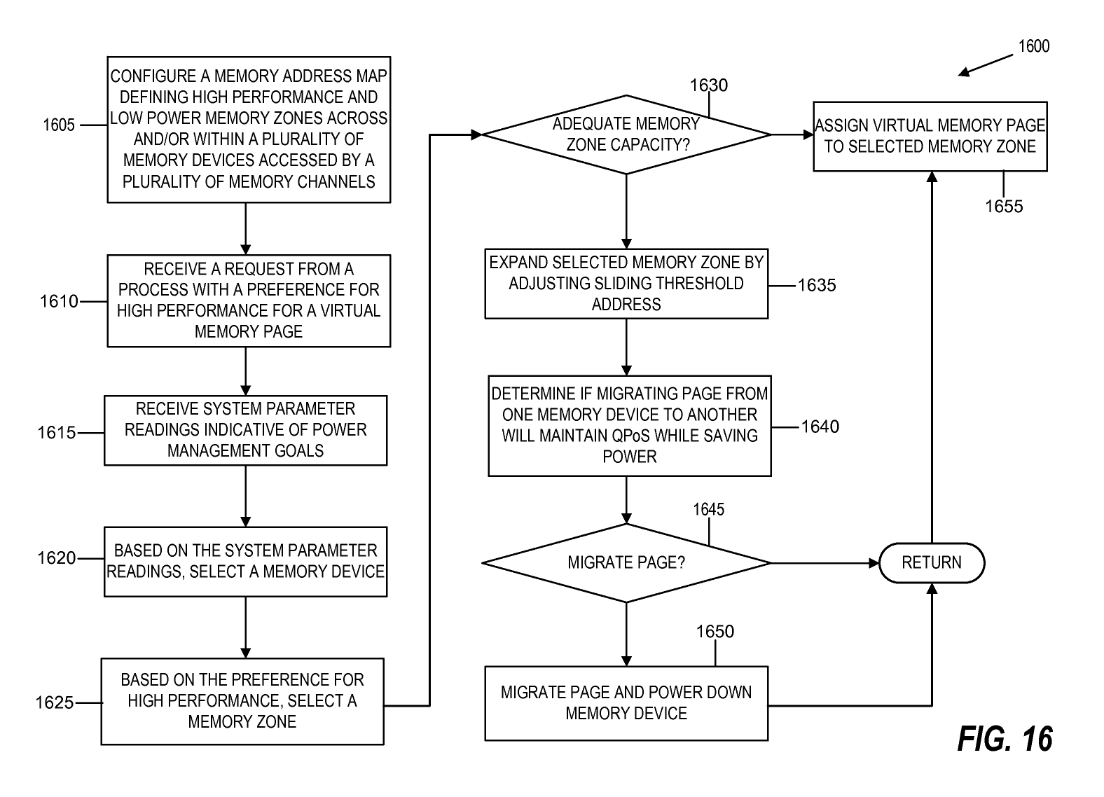

FIG. 16 is a flowchart illustrating an embodiment of a method 1600 implemented in the system of FIG. 12 for page-by-page memory channel interleaving using dynamic partial channel interleaving memory management techniques to dynamically adjust, create and modify memory zones based on QPoS levels. Beginning at block 1605, a memory address map may be configured to define memory zones across and within multiple memory devices and across multiple memory channels. As described previously, it is envisioned that the memory devices may not all be of the same type and, as such, certain memory zones may be defined across multiple memory devices of a first type while certain other memory zones are defined across multiple memory devices of a second type. Moreover, certain memory zones may be defined within a single memory device, accessible by a certain memory channel or plurality of memory channels. The memory zones may be defined in view of providing a particular QPoS level to applications requesting virtual memory addresses for their transactions. For example, a certain memory zone may be accessible on a pair of high performance memory channels operable to interleave pages across a pair of high performance memory devices. Such a zone may be useful for maintaining a high level of performance, although it may necessitate a high level of power consumption as well. It is envisioned that multiple zones with multiple QPoS levels may be defined and made available for memory page allocation depending on the preference of the requesting application and the real-time conditions across the SoC.

Returning to the method 1600, at block 1610, a request for a virtual memory page allocation in a high performance zone may be received. Generally, such a request may default to an interleaved zone that leverages the bandwidth of multiple channels accessing multiple memory devices. By contrast, a request for a low power page allocation may default to a linear zone that leverages a single channel accessing a single memory device subject to a linear mapping protocol.

At block 1615, the system parameter readings indicative of power limits, power consumption levels, power availability, remaining battery life and the like may be monitored. At blocks 1620 and 1625, the QPoS preference from the application API and the system parameter readings may be weighed by an optimization module to determine whether the QPoS preference should be overridden in favor of a more power efficient memory channel and device. In such a case, the optimization module may elect to allocate the virtual memory address to a low power zone instead of the preferred high power zone at the expense of the QoS requested by the application.

At decision block 1630, if adequate memory capacity exists in the selected memory zone the method follows to block 1655 and the virtual memory page is assigned to the memory zone. Otherwise, the method follows to block 1635. At block 1635, if the ideal memory zone has not been defined, or is defined but inadequate to accommodate the allocation, the optimization module may work to expand the ideal memory zone (or define it de novo) by dynamically adjusting a memory address range at the expense of an underutilized zone. At blocks 1640 and 1650, the optimization module may also determine that certain transactions or pages may be redirected or migrated to a different zone so that the memory channel and memory device associated with the current zone may be powered down or otherwise taken offline to conserve energy.

It is envisioned that the optimization module may migrate (or make an initial allocation of) pages to an existing zone or to a newly created zone. To create a new zone, memory capacity associated with the free zone (see FIG. 14, for example) may be designated for the new zone and/or an existing zone may be “torn down” in order to free up capacity for the new zone. The new zone may be an interleaved zone, a linear zone or a mixed interleave-linear zone, as determined by the optimization module to deliver the required QPoS and optimize memory usage.

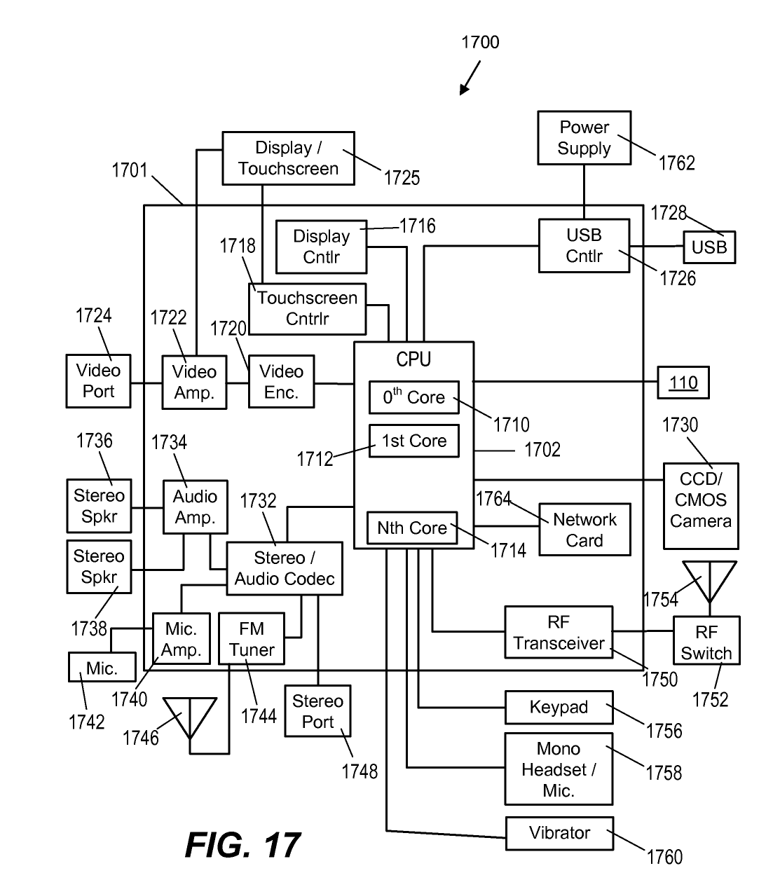

As mentioned above, the system 100 may be incorporated into any desirable computing system. FIG. 17 illustrates the system 100 incorporated in an exemplary portable computing device (PCD) 1700. The system 100 may be included on the SoC 1701, which may include a multicore CPU 1702. The multicore CPU 1702 may include a zeroth core 1710, a first core 1712, and an Nth core 1714. One of the cores may comprise, for example, a graphics processing unit (GPU) with one or more of the others comprising the CPU 104 (FIGS. 1 and 12). According to alternate exemplary embodiments, the CPU 1702 may also comprise those of single core types and not one which has multiple cores, in which case the CPU 104 and the GPU may be dedicated processors, as illustrated in system 100.

A display controller 1716 and a touch screen controller 1718 may be coupled to the CPU 1702. In turn, the touch screen display 1725 external to the on-chip system 1701 may be coupled to the display controller 1716 and the touch screen controller 1718.

FIG. 17 further shows that a video encoder 1720, e.g., a phase alternating line (PAL) encoder, a sequential color a memoire (SECAM) encoder, or a national television system(s) committee (NTSC) encoder, is coupled to the multicore CPU 1702. Further, a video amplifier 1722 is coupled to the video encoder 1720 and the touch screen display 1725. Also, a video port 1724 is coupled to the video amplifier 1722. As shown in FIG. 17, a universal serial bus (USB) controller 1726 is coupled to the multicore CPU 1702. Also, a USB port 1728 is coupled to the USB controller 1726. Memory 110 and 118 and a subscriber identity module (SIM) card 1746 may also be coupled to the multicore CPU 1702. Memory 110 may comprise memory devices 110 and 118 (FIGS. 1 and 12), as described above.

Further, as shown in FIG. 17, a digital camera 1730 may be coupled to the multicore CPU 1702. In an exemplary aspect, the digital camera 1730 is a charge-coupled device (CCD) camera or a complementary metal-oxide semiconductor (CMOS) camera.

As further illustrated in FIG. 17, a stereo audio coder-decoder (CODEC) 1732 may be coupled to the multicore CPU 1702. Moreover, an audio amplifier 1734 may coupled to the stereo audio CODEC 1732. In an exemplary aspect, a first stereo speaker 1736 and a second stereo speaker 1738 are coupled to the audio amplifier 1734. FIG. 17 shows that a microphone amplifier 1740 may be also coupled to the stereo audio CODEC 1732. Additionally, a microphone 1742 may be coupled to the microphone amplifier 1740. In a particular aspect, a frequency modulation (FM) radio tuner 1744 may be coupled to the stereo audio CODEC 1732. Also, an FM antenna 1746 is coupled to the FM radio tuner 1744. Further, stereo headphones 1748 may be coupled to the stereo audio CODEC 1732.

FIG. 17 further illustrates that a radio frequency (RF) transceiver 1750 may be coupled to the multicore CPU 1702. An RF switch 1752 may be coupled to the RF transceiver 1750 and an RF antenna 1754. As shown in FIG. 17, a keypad 1756 may be coupled to the multicore CPU 1702. Also, a mono headset with a microphone 1758 may be coupled to the multicore CPU 1702. Further, a vibrator device 1760 may be coupled to the multicore CPU 1702.

FIG. 17 also shows that a power supply 1762 may be coupled to the on-chip system 1701. In a particular aspect, the power supply 1762 is a direct current (DC) power supply that provides power to the various components of the PCD 1700 that require power. Further, in a particular aspect, the power supply is a rechargeable DC battery or a DC power supply that is derived from an alternating current (AC) to DC transformer that is connected to an AC power source.

FIG. 17 further indicates that the PCD 1700 may also include a network card 1764 that may be used to access a data network, e.g., a local area network, a personal area network, or any other network. The network card 1764 may be a Bluetooth network card, a WiFi network card, a personal area network (PAN) card, a personal area network ultra-low-power technology (PeANUT) network card, a television/cable/satellite tuner, or any other network card well known in the art. Further, the network card 1764 may be incorporated into a chip, i.e., the network card 388 may be a full solution in a chip, and may not be a separate network card.

It should be appreciated that one or more of the method steps described herein may be stored in the memory as computer program instructions, such as the modules described above. These instructions may be executed by any suitable processor in combination or in concert with the corresponding module to perform the methods described herein.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example.

Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the Figures which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, NAND flash, NOR flash, M-RAM, P-RAM, R-RAM, CD-ROM or other optical disk storage, magnetic disk storage or other magnetic storage devices, or any other medium that may be used to carry or store desired program code in the form of instructions or data structures and that may be accessed by a computer.

Also, any connection is properly termed a computer-readable medium. For example, if the software is transmitted from a website, server, or other remote source using a coaxial cable, fiber optic cable, twisted pair, digital subscriber line (“DSL”), or wireless technologies such as infrared, radio, and microwave, then the coaxial cable, fiber optic cable, twisted pair, DSL, or wireless technologies such as infrared, radio, and microwave are included in the definition of medium.

Disk and disc, as used herein, includes compact disc (“CD”), laser disc, optical disc, digital versatile disc (“DVD”), floppy disk and blu-ray disc where disks usually reproduce data magnetically, while discs reproduce data optically with lasers. Combinations of the above should also be included within the scope of computer-readable media.

Alternative embodiments will become apparent to one of ordinary skill in the art to which the invention pertains without departing from its spirit and scope. Therefore, although selected aspects have been illustrated and described in detail, it will be understood that various substitutions and alterations may be made therein without departing from the spirit and scope of the present invention, as defined by the following claims.

What is claimed is:

1. A dynamic memory channel interleaving method in a system on a chip, comprising:
configuring a memory address map for two or more memory devices accessed via two or more respective memory channels with a plurality of memory zones, wherein the two or more memory devices comprise at least one memory device of a first type and at least one memory device of a second type and the plurality of memory zones comprise at least one high performance memory zone and at least one low power memory zone;
receiving a request from a process for a virtual memory page, the request comprising a preference for high performance;
receiving one or more system parameter readings, wherein the system parameter readings indicate one or more power management goals in the system on a chip;
based on the system parameter readings, selecting the at least one memory device of the first type;
based on the preference for high performance, determining a preferred memory zone within the at least one memory device of the first type, wherein the preferred memory zone is a high performance memory zone; and
assigning the virtual memory page to a free physical page in the preferred memory zone.

2. The method of claim 1, wherein the preferred memory zone is an interleaved memory zone.

3. The method of claim 1, further comprising:
in the at least one memory device of the first type, defining a boundary between the preferred memory zone and a low power memory zone using a sliding threshold address;
determining that the preferred memory zone requires expansion; and
expanding the preferred memory zone by modifying the sliding threshold address such that the low power memory zone is reduced.

4. The method of claim 3, wherein the sliding threshold address comprises a linear end address and an interleave start address.

5. The method of claim 1, wherein the assigning the virtual memory page to a free physical page in the preferred memory zone comprises:
instructing a memory channel interleaver.

6. The method of claim 1, further comprising:
migrating the virtual memory page from the preferred memory zone within the at least one memory device of the first type to an alternative memory zone; and
powering down the at least one memory device of the first type, wherein powering down the at least one memory device of the first type reduces overall power consumption of the system on a chip.

7. The method of claim 1, wherein the at least one memory device of the first type comprises a dynamic random access memory (DRAM) device.

8. The method of claim 1, wherein the system on a chip is comprised within a wireless telephone.

9. A dynamic memory channel interleaving system, comprising:
means for configuring a memory address map for two or more memory devices accessed via two or more respective memory channels with a plurality of memory zones, wherein the two or more memory devices comprise at least one memory device of a first type and at least one memory device of a second type and the plurality of memory zones comprise at least one high performance memory zone and at least one low power memory zone;
means for receiving a request from a process for a virtual memory page, the request comprising a preference for high performance;
means for receiving one or more system parameter readings, wherein the system parameter readings indicate one or more power management goals in the system on a chip;
based on the system parameter readings, means for selecting the at least one memory device of the first type;
based on the preference for high performance, means for determining a preferred memory zone within the at least one memory device of the first type, wherein the preferred memory zone is a high performance memory zone; and
means for assigning the virtual memory page to a free physical page in the preferred memory zone.

10. The system of claim 9, wherein the preferred memory zone is an interleaved memory zone.

11. The system of claim 9, further comprising:
means for defining, in the at least one memory device of the first type, a boundary between the preferred memory zone and a low power memory zone using a sliding threshold address;
means for determining that the preferred memory zone requires expansion; and
means for expanding the preferred memory zone by modifying the sliding threshold address such that the low power memory zone is reduced.

12. The system of claim 11, wherein the sliding threshold address comprises a linear end address and an interleave start address.

13. The system of claim 9, wherein the means for assigning the virtual memory page to a free physical page in the preferred memory zone comprises:
means for instructing a memory channel interleaver.

14. The system of claim 9, further comprising:
means for migrating the virtual memory page from the preferred memory zone within the at least one memory device of the first type to an alternative memory zone; and
means for powering down the at least one memory device of the first type, wherein powering down the at least one memory device of the first type reduces overall power consumption of the system on a chip.

15. The system of claim 9, wherein the at least one memory device of the first type comprises a dynamic random access memory (DRAM) device.

16. The system of claim 9, wherein the system is comprised within a wireless telephone.

17. A dynamic memory channel interleaving system, comprising:
a monitor module configured to monitor memory request preferences and system parameter readings, wherein the system parameter readings indicate one or more power management goals in a system on a chip; and
an optimization module in communication with the monitor module and an interleaver, the interleaver in communication with two or more memory devices accessed via two or more respective memory channels, the optimization module configured to:
configure a memory address map for the two or more memory devices accessed via two or more respective memory channels with a plurality of memory zones, wherein the two or more memory devices comprise at least one memory device of a first type and at least one memory device of a second type and the plurality of memory zones comprise at least one high performance memory zone and at least one low power memory zone;
receive a request from a process for a virtual memory page, the request comprising a preference for high performance;
receive one or more system parameter readings, wherein the system parameter readings indicate one or more power management goals in the system on a chip;
based on the system parameter readings, select the at least one memory device of the first type;
based on the preference for high performance, determine a preferred memory zone within the at least one memory device of the first type, wherein the preferred memory zone is a high performance memory zone; and
assign the virtual memory page to a free physical page in the preferred memory zone.

18. The system of claim 17, wherein the preferred memory zone is an interleaved memory zone.

19. The system of claim 17, the optimization module further configured to:
in the at least one memory device of the first type, define a boundary between the preferred memory zone and a low power memory zone using a sliding threshold address;
determine that the preferred memory zone requires expansion; and
expand the preferred memory zone by modifying the sliding threshold address such that the low power memory zone is reduced.

20. The system of claim 19, wherein the sliding threshold address comprises a linear end address and an interleave start address.

21. The system of claim 17, wherein the assigning the virtual memory page to a free physical page in the preferred memory zone comprises:
instructing a memory channel interleaver.

22. The system of claim 17, the optimization module further configured to:
migrate the virtual memory page from the preferred memory zone within the at least one memory device of the first type to an alternative memory zone; and
power down the at least one memory device of the first type, wherein powering down the at least one memory device of the first type reduces overall power consumption of the system on a chip.

23. The system of claim 17, wherein the at least one memory device of the first type comprises a dynamic random access memory (DRAM) device.

24. A computer program product comprising a non-transitory computer usable medium having a computer readable program code embodied therein, the computer readable program code adapted to be executed to implement a method for dynamic memory channel interleaving in a system on a chip, comprising:
configuring a memory address map for two or more memory devices accessed via two or more respective memory channels with a plurality of memory zones, wherein the two or more memory devices comprise at least one memory device of a first type and at least one memory device of a second type and the plurality of memory zones comprise at least one high performance memory zone and at least one low power memory zone;
receiving a request from a process for a virtual memory page, the request comprising a preference for high performance;
receiving one or more system parameter readings, wherein the system parameter readings indicate one or more power management goals in the system on a chip;
based on the system parameter readings, selecting the at least one memory device of the first type;
based on the preference for high performance, determining a preferred memory zone within the at least one memory device of the first type, wherein the preferred memory zone is a high performance memory zone; and
assigning the virtual memory page to a free physical page in the preferred memory zone.

25. The computer program product of claim 24, wherein the preferred memory zone is an interleaved memory zone.

26. The computer program product of claim 24, further comprising:
in the at least one memory device of the first type, defining a boundary between the preferred memory zone and a low power memory zone using a sliding threshold address;
determining that the preferred memory zone requires expansion; and
expanding the preferred memory zone by modifying the sliding threshold address such that the low power memory zone is reduced.

27. The computer program product of claim 26, wherein the sliding threshold address comprises a linear end address and an interleave start address.

28. The computer program product of claim 24, wherein the assigning the virtual memory page to a free physical page in the preferred memory zone comprises:
instructing a memory channel interleaver.

29. The computer program product of claim 24, further comprising:
migrating the virtual memory page from the preferred memory zone within the at least one memory device of the first type to an alternative memory zone; and
powering down the at least one memory device of the first type, wherein powering down the at least one memory device of the first type reduces overall power consumption of the system on a chip.

30. The computer program product of claim 24, wherein the at least one memory device of the first type comprises a dynamic random access memory (DRAM) device.
